(19) United States
(12) Patent Application Publication
(10) Pub. No.: US 2026/0262233 A1
(43) Pub. Date: Sep. 3, 2026

(54) MODULE AND METHOD FOR MANUFACTURING SAME

(71) Applicant: ULTRAMEMORY INC., Tokyo (JP)

(72) Inventors: Shigeru NAKAHARA, Tokyo (JP); Fumitake OKUTSU, Tokyo (JP); Masatoshi HASEGAWA, Tokyo (JP); Kazuhiko KAJIGAYA, Tokyo (JP); Kazuo KATO, Tokyo (JP)

(21) Appl. No.: 19/654,233

(22) Filed: Apr. 21, 2026

Related U.S. Application Data
(62) Division of application No. 18/550,433, filed on Apr. 8, 2021.

(51) Int. Cl. H10B 80/00; H10B 99/00; H10P 54/00; H10W 20/00; H10W 70/09; H10W 70/60; H10W 72/00; H10W 74/01; H10W 74/10; H10W 90/00

(52) U.S. Cl. CPC H10B 80/00; H10B 99/10; H10P 54/00; H10W 20/023; H10W 74/014; H10W 74/111; H10W 90/00; H10W 70/09; H10W 70/60; H10W 72/0198

(57) ABSTRACT

A module includes a plurality of stacked memories. The plurality of stacked memories each includes memory chips stacked by bump-less connection, and a logic chip stacked on the stacked memories that are juxtaposed to each other in a direction intersecting with a stacking direction of the stacked memories in such a manner that the logic chip straddles the stacked memories.

### CROSS REFERENCE TO RELATED APPLICATIONS

This application is a Divisional of co-pending application Ser. No. 18/550,433, filed on Sep. 13, 2023, which is a U.S. National Stage of International Application No. PCT/JP2021/014944 filed on Apr. 8, 2021, for which priority is claimed under 35 U.S.C. § 120, the entire contents of all of which are hereby incorporated by reference.

### TECHNICAL FIELD

The present invention relates to a module and a method for manufacturing such a module.

### BACKGROUND ART

Conventionally, a volatile memory (RAM) such as a dynamic random access memory (DRAM) has been known as a storage device. The DRAM is required to have a large capacity such that it can support high performance of an arithmetic unit (hereinafter referred to as a logic chip) and an increase in an amount of data. For this reason, attempts have been made to increase the capacity by way of miniaturization of the memory (memory cell array, memory chip) and planar addition of cells. On the other hand, this type of increase in capacity is reaching its limit because of the miniaturization resulting in feebleness to noise, an increase in chip area, and other factors.

Therefore, in recent years, a technique for achieving a large capacity by way of a three-dimensional (3D) structure that is formed by stacking a plurality of planar memories has been developed. In addition, as the amount of data increases, the speed of data communication between chips (a logic chip and a memory chip) has been increased (for example, see Patent Documents 1 and 2).

Patent Document 1: US Patent publication No. 2015/0171015

Patent Document 2: US Patent publication No. 2017/0062383

### DISCLOSURE OF THE INVENTION

### Problems to Be Solved by the Invention

Patent Document 1 discloses a semiconductor module having a configuration in which bridge connection is established between two chips. The semiconductor module of Patent Document 1 includes an additional chip such as a stacked memory connected via an additional wiring structure. The entirety of the semiconductor module of Patent Document 1 is sealed with a molding material while forming a build-up wiring layer, and has bumps on its surface which are for connection to a package substrate.

Patent Document 2 discloses a semiconductor module having a configuration in which a logic chip and a memory chip are arranged on a carrier substrate and sealed with a molding material. According to Patent Document 2, a redistribution layer and a through via are formed on the molding material. The semiconductor module of Patent Document 2 includes an interposer disposed so as to straddle the logic chip and the memory chip. Furthermore, a further redistribution layer and bumps are sequentially formed on the interposer of the semiconductor module of Patent Document 2.

The semiconductor module of Patent Document 1 tends to increase in cost due to an I/O connection structure for the bridge connection and the build-up wiring for connection to the bumps. The semiconductor module of Patent Document 2 also tends to increase in cost because it requires formation of the further redistribution layer and the through via, resulting in an increase in the number of process steps. It is favorable to reduce the cost for manufacturing a module including a plurality of chips.

The present invention has been achieved in view of the disadvantages described above, and it is an object of the present invention to provide a module including a plurality of chips and manufactured at a reduced cost and a method for manufacturing such a module.

### Means for Solving the Problems

The present invention relates to method for manufacturing a module including a predetermined number of stacked memories. The method includes: a stacked wafer forming step of forming a stacked wafer by stacking a plurality of memory wafers in a bump-less manner; a dicing step of dicing the stacked wafer into the stacked memories as individual pieces; a rearrangement step of rearranging a plurality of the stacked memories in a predetermined shape; a molding step of molding the stacked memories that have been rearranged; a wiring forming step of forming external wiring on the stacked memories; and a separation step of separating a resultant semifinished product into memory modules each including a predetermined number of the stacked memories that have been molded.

Preferably, the method for manufacturing the module further includes, after the rearrangement step and before the molding step, an external through electrode forming step of forming an external through electrode that extends in a stacking direction of the stacked memories. It is preferable that in the rearrangement step, the stacked memories as the individual pieces are disposed on each other and rearranged in a predetermined shape, and in the molding step, the stacked memories that have been rearranged and the external through electrode are molded.

It is preferable that in the rearrangement step, the stacked memories and a logic chip are rearranged in a predetermined shape, and in the molding step, the stacked memories and the logic chip are molded.

It is preferable that in the rearrangement step, the logic chip is stacked on the plurality of stacked memories.

It is preferable that in the rearrangement step, the logic chip is stacked on the plurality of stacked memories so as to straddle the plurality of stacked memories.

It is preferable that in the rearrangement step, the stacked memories are stacked on the logic chip.

The present invention relates to a method for manufacturing a module including a predetermined number of stacked memories. The method including: a stacked wafer forming step of forming a stacked wafer by stacking a plurality of memory wafers in a bump-less manner; a rearrangement step of stacking a logic chip such that the logic chip straddles a plurality of stacked memories included in the stacked wafer; and a separation step of separating the stacked wafer having the logic chip stacked thereon into memory modules each including a predetermined number of the stacked memories.

It is preferable that in the rearrangement step, the logic chip is stacked on a control chip that is exposed on one surface of the stacked wafer in a stacking direction and that controls the operation of the stacked memories.

The present invention relates to a module provided with a predetermined number of stacked memories. The module including: the predetermined number of stacked memories each including memory chips stacked by bump-less connection; a packaging part that packages the predetermined number of stacked memories; and an external wiring disposed on one surface of the stacked memories in a stacking direction.

Preferably, the module further includes a logic chip stacked on the stacked memories, and the packaging part packages the logic chip and the stacked memories.

Preferably, the module further includes a logic chip juxtaposed to the stacked memories in a direction intersecting with a stacking direction of the stacked memories, and the packaging part packages the logic chip and the predetermined number of memories.

Preferably, the module further includes an external through electrode that extends in a stacking direction of the stacked memories. It is preferable that a plurality of the stacked memories are stacked in the stacking direction, the packaging part further packages the external through electrode, and the external wiring is disposed on one surface of the stacked memory, the one surface being exposed from the packaging part.

The present invention relates to a module provided with a plurality of stacked memories. The module includes: the plurality of stacked memories each including memory chips stacked by bump-less connection; and a logic chip stacked on the stacked memories that are juxtaposed to each other in a direction intersecting with a stacking direction of the stacked memories in such a manner that the logic chip straddles the stacked memories.

It is preferable that each stacked memory comprises the memory chips, and a control chip that is exposed on one surface in a stacking direction and controls operation of the memory chips.

### Effects of the Invention

The present invention provides a module including a plurality of chips and manufactured at a reduced cost, and a method for manufacturing such a module.

### BRIEF DESCRIPTION OF THE DRAWINGS

FIG. 1 is a plan view illustrating a module according to a first embodiment of the present invention;

FIG. 2 is a cross-sectional view taken along line A-A in FIG. 1;

FIG. 3 is a schematic view illustrating a process of manufacturing the module according to the first embodiment;

FIG. 4 is a plan view illustrating a stacked wafer for use for manufacturing the module according to the first embodiment;

FIG. 5 is a schematic plan view illustrating a process of manufacturing the module according to the first embodiment;

FIG. 6 is a schematic cross-sectional view illustrating a process of manufacturing the module according to the first embodiment;

FIG. 7 is a plan view illustrating a module according to a second embodiment of the present invention;

FIG. 8 is a cross-sectional view illustrating a module according to a third embodiment of the present invention;

FIG. 9 is a cross-sectional view illustrating a module according to a fourth embodiment of the present invention;

FIG. 10 is a cross-sectional view illustrating a module according to a fifth embodiment of the present invention;

FIG. 11 is a cross-sectional view illustrating a module according to a sixth embodiment of the present invention;

FIG. 12 is a cross-sectional view illustrating a module according to a seventh embodiment of the present invention;

FIG. 13 is a cross-sectional view illustrating a module according to an eighth embodiment of the present invention;

FIG. 14 is a cross-sectional view illustrating a module according to a ninth embodiment of the present invention;

FIG. 15 is a cross-sectional view illustrating another example of the module of the ninth embodiment;

FIG. 16 is a cross-sectional view illustrating another example of the module of the ninth embodiment;

FIG. 17 is a schematic diagram illustrating a relationship between a stacked wafer and a processor when manufacturing the module according to the ninth embodiment;

FIG. 18 is a schematic diagram illustrating another example of a relationship between a stacked wafer and a processor when manufacturing a module according to a modification;

FIG. 19 is a schematic diagram illustrating yet another example of a relationship between a stacked wafer and a processor when manufacturing a module according to a modification; and

FIG. 20 is a schematic diagram illustrating yet another example of a relationship between a stacked wafer and a processor when manufacturing a module according to a modification.

### PREFERRED MODE FOR CARRYING OUT THE INVENTION

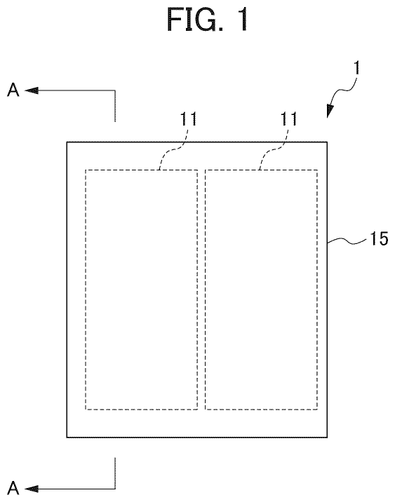

In the following, a module 1 according to each embodiment of the present invention and a manufacturing method thereof will be described with reference to FIGS. 1 to 20. First, an outline of the module 1 according to each embodiment will be described.

The module 1 according to each embodiment is manufactured using the fan out wafer level package (FOWLP) technology, without a Si interposer or a Si bridge. Thus, the module 1, which does not have to include a package substrate or the like, can be manufactured inexpensively. The module 1 of each embodiment is a multichip module (MCM) 1 including a plurality of stacked memories 11 or a logic chip 20. In particular, the module 1 of each embodiment is produced by modularizing memory chips 110, which are individual pieces obtained by dicing a stacked memory including wafers stacked in a bump-less manner, using the FOWLP technology. As a result, a thin MCM with a low height can be manufactured.

### First Embodiment

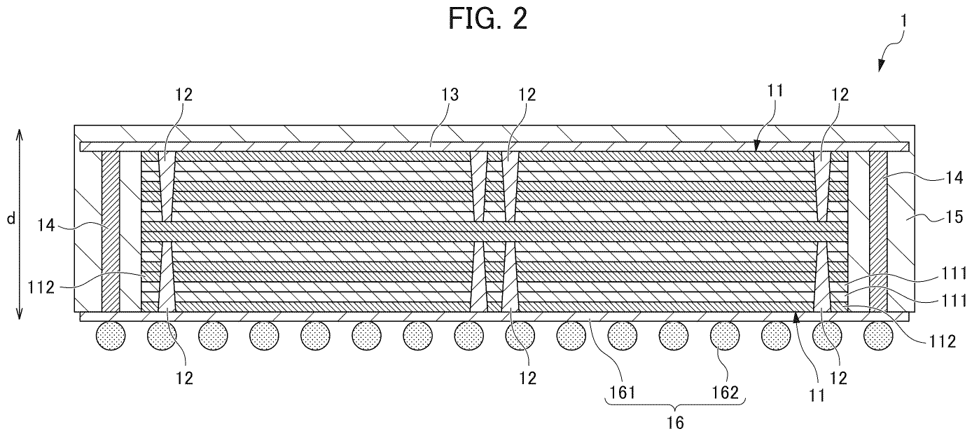

Next, the module 1 according to a first embodiment of the present invention and a manufacturing method thereof will be described with reference to FIGS. 1 to 6. As illustrated in FIG. 1, the module 1 according to the first embodiment includes a predetermined number of stacked memories 11. Specifically, in the module 1, the stacked memories 11 are juxtaposed to each other in a direction intersecting with a stacking direction d as illustrated in FIG. 1, while being disposed on each other in the stacking direction d as illustrated in FIG. 2. In the present embodiment, two stacked memories 11 disposed on each other in the stacking direction d form one set of stacked memories, and the module 1 includes two juxtaposed sets of stacked memories 11. The module 1 includes the stacked memories 11, internal through electrodes 12, an internal redistribution layer 13, external through electrodes 14, a packaging part 15, and external wiring 16.

Each stacked memory 11 includes memory chips 110 stacked together by bump-less connection. Each stacked memory 11 is formed by stacking, by bump-less connection, the memory chips 110 each having an Si layer 112 constituting one surface thereof and a wiring layer 111 constituting the other surface thereof, for example. Specifically, a pair of memory chips 110 are connected to each other by bump-less connection with their wiring layers facing each other, and two or more pairs of memory chips 110 are stacked on each other by bump-less connection, whereby the stacked memory 11 is formed. In the present embodiment, each stacked memory 11 includes four memory chips 110 stacked together. The memory chips 110 stacked to form each stacked memory 11 have a rectangular shape of the same size when viewed in plan view along the stacking direction d.

Each internal through electrode 12 is an electrode penetrating the stacked memory 11. For example, each internal through electrode 12 penetrates the stacked memory chips 110 in the stacking direction d, from one surface of the stacked memory 11. In the present embodiment, each internal through electrode 12 penetrates the wiring layers 111 of all the memory chips 110 included in one stacked memory 11 from one surface of the one stacked memory 11. Four internal through electrodes 12 are arranged in the cross section taken along the line A-A in FIG. 1.

The internal redistribution layer 13 is stacked on one surface of one set of the stacked memories 11 in the stacking direction d. The internal redistribution layer 13 is electrically connected to the internal through electrodes 12 of an adjacent one of the stacked memories 11 included in the one set of stacked memories 11. When viewed in plan view, the internal redistribution layer 13 has a rectangular shape of larger dimensions than the rectangular stacked memory 11. In other words, the internal redistribution layer 13 is disposed with its side edges protruding with respect to the edges of the stacked memory 11 in the direction intersecting with the stacking direction d.

The external through electrodes 14 extend in the stacking direction d of the stacked memories 11. Each external through electrode 14 is, for example, a Cu pillar. One end of each external through electrode 14 is electrically connected to the internal redistribution layer 13. In the present embodiment, a pair of the external through electrodes 14 are arranged while sandwiching the stacked memories 11 therebetween in the cross section taken along the line A-A.

The packaging part 15 packages a predetermined number of stacked memories 11. The packaging part 15 is formed of, for example, a molding material such as resin. For example, as illustrated in FIGS. 1 and 2, the packaging part 15 packages the outer periphery of the assemblage of the stacked memories 11, except for one surface in the stacking direction d of the assemblage of the stacked memories 11. The packaging part 15 further packages the internal redistribution layer 13 and the external through electrodes 14.

The external wiring 16 is disposed on one surface of the assemblage of the stacked memories 11 in the stacking direction d. Specifically, the external wiring 16 is disposed on the one surface of the assemblage of the stacked memories 11 that is exposed from the packaging part 15. The external wiring 16 includes an external redistribution layer 161 and solder balls 162.

The external redistribution layer 161 is provided on the one surface of the assemblage of the stacked memories 11 that is exposed from the packaging part 15. The external wiring 16 has a rectangular shape of the same dimensions as those of the internal redistribution layer 13 when viewed in plan view. The external redistribution layer 161 is electrically connected to the internal through electrodes 12 of an adjacent one of the stacked memories 11 included in one set of stacked memories 11. The external redistribution layer 161 is electrically connected to the other end of each external through electrode 14.

The solder balls 162 are arranged on an exposed surface of the external redistribution layer 161. The solder balls 162 are electrically connected to the external redistribution layer 161. In this embodiment, the plural solder balls 162 are arranged along the exposed surface of the external redistribution layer 161.

Next, an operation of the module 1 will be described. The module 1 is electrically connected to another substrate or the like via the solder balls 162. The stacked memories 11 adjacent to the external redistribution layer in the stacking direction d are capable of transmitting and receiving data via the internal through electrodes 12, the external redistribution layer 161, and the solder balls 162. The stacked memories 11 adjacent to the internal redistribution layer 13 in the stacking direction d are capable of transmitting and receiving data via the internal through electrodes 12, the internal redistribution layer 13, the external through electrodes 14, the external redistribution layer 161, and the solder balls 162.

Next, a method for manufacturing the module 1 will be described. The method is for manufacturing the module 1 including a predetermined number of stacked memories 11. The method for manufacturing the module 1 includes a stacked wafer forming step, a dicing step, a rearrangement step, an external through electrode forming step, a molding step, an internal redistribution layer forming step, a wiring forming step, and a separation step.

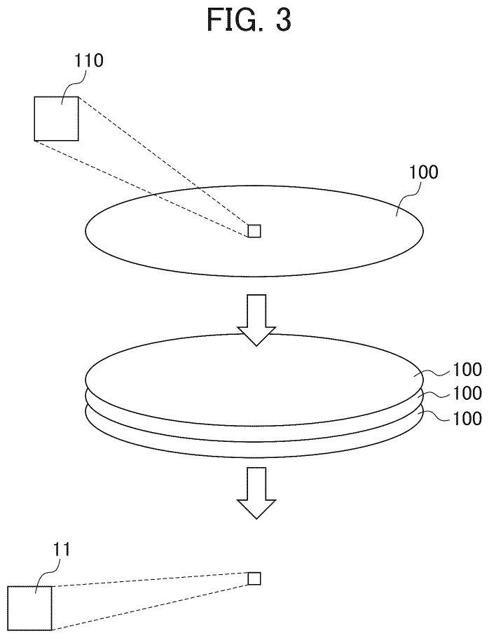

First, the stacked wafer forming step is performed to form a stacked wafer including a plurality of memory wafers 100 stacked in a bump-less manner. In the stacked wafer forming step, as illustrated in FIG. 3, the stacked wafer is formed by connecting, by bump-less connection, the wafers that are to constitute memory chips 110. Thus, the stacked wafer includes a plurality of stacked memories 11 each including the memory chips 110 stacked together. Internal through electrodes 12 are formed in each stacked memory 11.

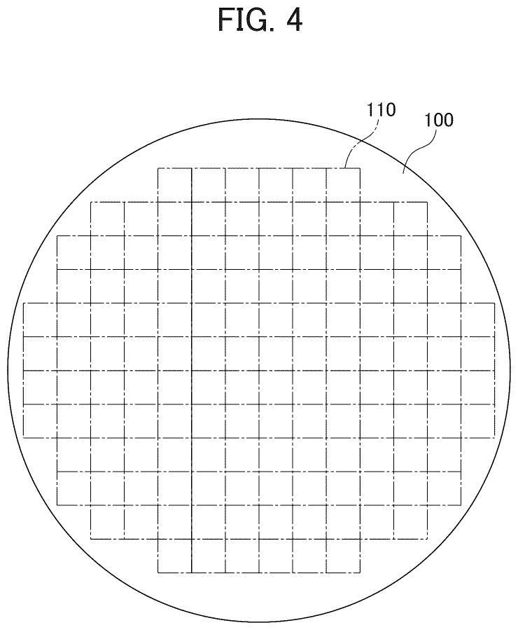

Next, the dicing step is performed. In the dicing step, the stacked wafer is diced into the stacked memories 11 as individual pieces. As illustrated in FIG. 4, in the dicing step, the stacked memory 11 illustrated in FIG. 3 is produced by dicing the wafer into pieces that have a rectangular shape when viewed in plan view.

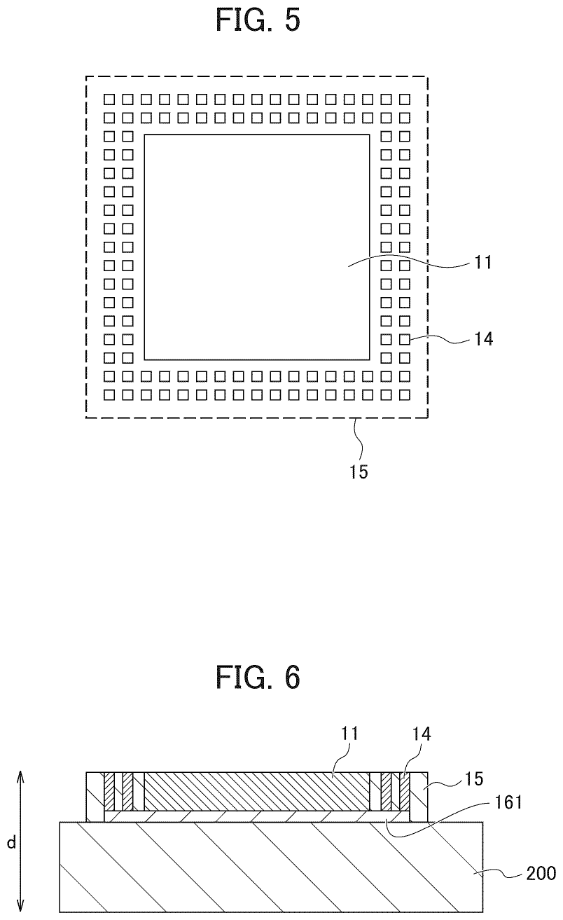

Next, the rearrangement step is performed. In the rearrangement step, the plurality of stacked memories 11 are rearranged in a predetermined shape on a carrier substrate 200. The carrier substrate 200 is made of silicon, glass, or the like. The carrier substrate 200 typically has a circular or rectangular plate shape. Furthermore, in the rearrangement step, the stacked memories 11 as individual pieces are disposed on each other into a predetermined shape. In the rearrangement step, for example, a plurality of stacked memories 11 are stacked in the stacking direction d, thereby forming one set. A plurality of sets of stacked memories 11 are juxtaposed to each other in a direction intersecting with the stacking direction d. In the rearrangement step of the present embodiment, as illustrated in FIGS. 1 and 2, four stacked memories 11 is composed of two sets of stacked memories 11, and each set includes two stacked memories disposed on each other. The two sets of stacked memories 11 are juxtaposed to each other in a direction intersecting with the stacking direction d, thereby forming one assemblage. In the rearrangement step, a plurality of the assemblages each including two sets of stacked memories 11 are juxtaposed to each other in a direction intersecting with the stacking direction d. For example, a plan view of the stacked memories 11 rearranged on the circular carrier substrate 200 is similar to FIG. 4. In this case, it can be assumed that the memory wafer 100 in FIG. 4 is replaced with the carrier substrate 200, and each memory chip 110 is replaced with a portion enclosed by a broken line in FIG. 5. The stacked memory 11 and the external through electrodes 14 are arranged in this portion.

Next, the external through electrode forming step is performed. As illustrated in FIGS. 5 and 6, in the external through electrode forming step, which is performed after the rearrangement step and before the molding step, external through electrodes 14 extending in the stacking direction d of the stacked memories 11 are formed. Furthermore, an external redistribution layer 161 is formed in the external through electrode forming step. First, in the external through electrode forming step, the external redistribution layer 161 is formed on the carrier substrate 200, as illustrated in FIG. 6. Next, in the external through electrode forming step, the external through electrodes 14 are formed on one surface of the external redistribution layer 161, which is exposed. Next, as illustrated in FIGS. 5 and 6, one set of stacked memories 11 is disposed in a region surrounded by the external through electrodes 14 and the external redistribution layer 161. The external through electrode forming step and the external redistribution layer forming step may be performed before the rearrangement step.

Next, the molding step is performed. In the molding step, as illustrated in FIG. 6, the stacked memories 11 that have been rearranged are molded. In the molding step of the present embodiment, the external through electrodes 14 and the rearranged stacked memory 11 are molded.

Next, the internal redistribution layer forming step is performed. In the internal redistribution layer forming step, an internal redistribution layer 13 is formed adjacent to one end of each external through electrode 14 and one surface in the stacking direction d of the stacked memory 11. In the internal redistribution layer forming step, the molding material is polished from one side in the stacking direction d, whereby the external through electrodes 14 and one surface in the stacking direction d of the stacked memories 11 are exposed. Subsequently, the internal redistribution layer 13 is formed. The internal redistribution layer 13 is then molded with a molding material.

Next, the wiring forming step is performed. In the wiring forming step, external wiring 16 is formed on the stacked memories 11. In the wiring forming step, solder balls 162 are arranged on the exposed surface of the external redistribution layer 161.

Next, the separation step is performed. In the separation step, the resultant semifinished product is separated into memory modules 1 each including a predetermined number of molded stacked memories 11. In the separation step, the resultant semifinished product is separated into pieces each including two sets of stacked memories 11, so that the modules 1 illustrated in FIGS. 1 and 2 are produced. In this manner, the module 1 is formed.

The above-described module 1 and manufacturing method thereof according to the first embodiment exert the following effects.
(1) A method for manufacturing the module 1 including a predetermined number of stacked memories 11 includes: a stacked wafer forming step of forming a stacked wafer by stacking a plurality of memory wafers 100 in a bump-less manner; a dicing step of dicing the stacked wafer into the stacked memories 11 as individual pieces; a rearrangement step of rearranging a plurality of stacked memories 11 in a predetermined shape; a molding step of molding the stacked memories 11 that have been rearranged; a wiring forming step of forming the external wiring 16 on the stacked memories 11; and a separation step of separating a resultant semifinished product into the memory modules 1 each including the predetermined number of molded stacked memories 11. The module 1 includes the predetermined number of stacked memories 11 each including a predetermined number of memory chips 110 stacked by bump-less connection, the packaging part 15 that packages the predetermined number of stacked memories 11, and the external wiring 16 disposed on one surface of the stacked memories 11 in the stacking direction d. As a result, the module 1 including a plurality of chips can be manufactured without using a package substrate or the like, whereby the module 1 can be manufactured inexpensively. The stacked memories 11 are modularized into the module 1 by the FOWLP technology. As a result, a thin MCM with a low height can be manufactured. At this time, since each stacked memory 11 is formed by stacking the memory chips in a bump-less manner, the thickness of the stacked memory 11 in the stacking direction d is as small as about ½ to ⅙ of the thickness of a typical stacked memory including pumps in a case where the stacked memory 11 and the typical stacked memory have the same number of layers of memory chips. Thus, a thin MCM including a large number of memory chips 110 and having a low height can be manufactured. Furthermore, it is possible to obtain a memory chip 110 whose height (thickness in the stacking direction d) is the same as the height of a memory chip included in another stacked memory 11. As a result, the heights after the rearrangement can be made uniform in a FOWLP process, whereby the yield of a step of forming a redistribution layer (RDL) and a step of arranging the solder balls 162 can be improved. Moreover, the memory chips 110 as individual pieces are stacked to be modularized into the module 1 by the FOWLP technology, whereby the small-area module 1 with a reduced footprint can be produced.
(2) The method for manufacturing the module 1 further includes: after the rearrangement step and before the molding step, and in the rearrangement step, the external through electrode forming step of forming the external through electrodes 14 that extends in the stacking direction d of the stacked memories 11. In the rearrangement step, the stacked memories 11 as individual pieces are disposed on each other and rearranged in a predetermined shape, and in the molding step, the rearranged stacked memories 11 and the external through electrodes 14 are molded. The module 1 further includes the external through electrodes 14 extending in the stacking direction d of the stacked memories 11, the plurality of stacked memories 11 are stacked in the stacking direction d, the packaging part 15 further packages the external through electrodes 14, and the external wiring 16 is disposed on one surface of the stacked memories 11 exposed from the packaging part 15. This configuration makes it possible to easily transmit power and a signal even between the stacked memories 11 disposed on each other, thereby improving the flexibility of arrangement.

### Second Embodiment

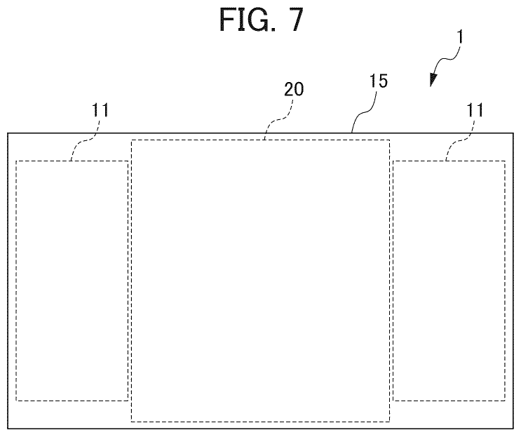

Next, a module 1 according to a second embodiment of the present invention and a manufacturing method thereof will be described with reference to FIG. 7. In the second embodiment, the same components as those described above are denoted by the same reference numerals, and the description thereof is simplified or omitted. As illustrated in FIG. 7, the module 1 according to the second embodiment differs from that of the first embodiment in that the module 1 according to the second embodiment further includes a logic chip 20 juxtaposed in a direction intersecting with a stacking direction d of stacked memories 11. The module 1 according to the second embodiment differs from that of the first embodiment in that the packaging part 15 according to the second embodiment packages the logic chip 20 and a predetermined number of memories. In the module 1 according to the second embodiment, the stacked memories 11 and the logic chip 20 are rearranged in a predetermined shape in a rearrangement step. In a molding step, the stacked memories 11 and the logic chip 20 are molded. In a separation step, a resultant semifinished product is separated into memory modules 1 each including a predetermined number of the stacked memories 11 and the logic chip 20.

The above-described module 1 and manufacturing method thereof according to the second embodiment exert the following effects.
(3) In the rearrangement step, the stacked memories 11 and the logic chip 20 are rearranged in a predetermined shape, in the molding step, the stacked memories 11 and the logic chip 20 are molded, and in the separation step, the resultant semifinished product is separated into memory modules 1 each including a predetermined number of the stacked memories 11 and the logic chip 20. The module 1 further includes the logic chip 20 juxtaposed in a direction intersecting with the stacking direction d of the stacked memories 11, and the packaging part 15 packages the logic chip 20 and the predetermined number of the memories. Thus, the manufacturing cost of the module 1 including the logic chip 20 can also be reduced.

### Third Embodiment

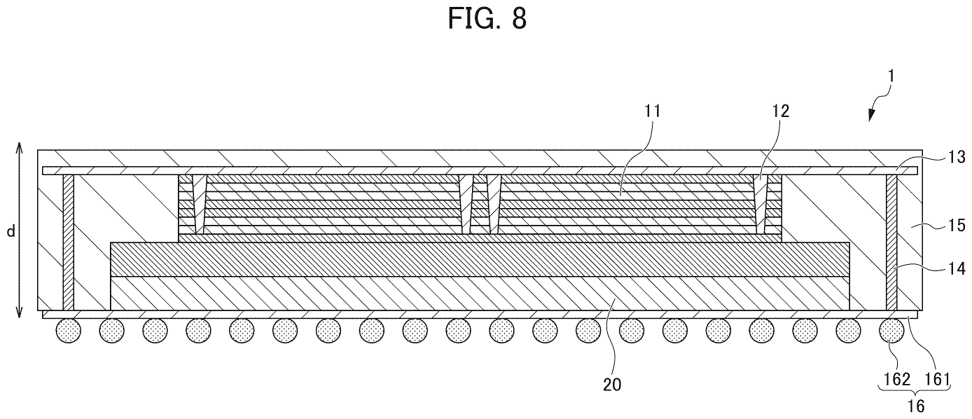

Next, a module 1 according to a third embodiment of the present invention will be described with reference to FIG. 8. In the third embodiment, the same components as those described above are denoted by the same reference numerals, and the description thereof is simplified or omitted. The module 1 according to the third embodiment is different from that of the first embodiment in that the module 1 of the third embodiment further includes a logic chip 20 stacked to stacked memories 11. The module 1 according to the third embodiment differs from that of the first embodiment in that the packaging part 15 according to the third embodiment packages the logic chip 20 and the stacked memories 11.

An external redistribution layer 161 is formed on one surface of the logic chip 20. The stacked memories 11 are arranged over the other surface of the logic chip 20. An internal redistribution layer 13 and an external redistribution layer 161 each have a rectangular shape in plan view, which is larger than the size the outer shape of the rectangular logic chip 20.

The above-described module 1 and manufacturing method thereof according to the third embodiment exert the following effects.
(4) In the rearrangement step, the logic chip 20 is stacked to the plurality of stacked memories 11. The module 1 further includes the logic chip 20 stacked to the stacked memories 11, and the packaging part 15 packages the logic chip 20 and the stacked memories 11. Due to this configuration, the module 1 can have a reduced size in plan view in comparison with a case where a logic chip 20 is juxtaposed to the stacked memories 11 in a direction intersecting with the stacking direction d of the stacked memories 11.

### Fourth Embodiment

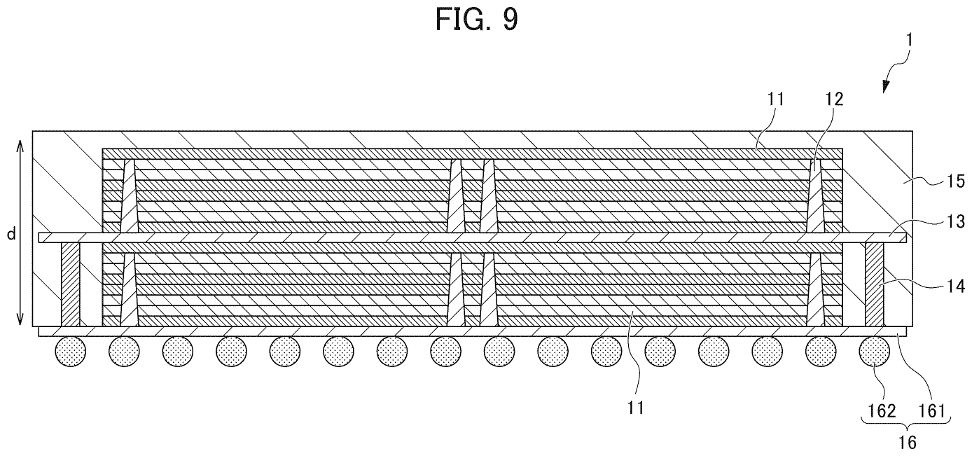

Next, a module 1 according to a fourth embodiment of the present invention will be described with reference to FIG. 9. In the fourth embodiment, the same components as those described above are denoted by the same reference numerals, and the description thereof is simplified or omitted. The module 1 according to the fourth embodiment differs from that of the first embodiment in that according to the fourth embodiment, an internal redistribution layer 13 is interposed between the stacked memories 11 that are disposed over each other. The method for manufacturing the module 1 according to the fourth embodiment differs from that of the first embodiment in that according to the fourth embodiment, after an internal redistribution layer forming step, a rearrangement step is performed in which the stacked memory 11 is disposed on the internal redistribution layer in the stacking direction d. The method for manufacturing the module 1 according to the fourth embodiment differs from that of the first embodiment in that according to the fourth embodiment, molding is performed after the stacked memories 11 have been disposed on the internal redistribution layer.

The above-described module 1 and manufacturing method thereof according to the fourth embodiment make it possible to reduce the height at which the internal redistribution layer 13 is positioned and shorten the length of the external through electrodes 14, thereby facilitating the manufacture of the module 1.

### Fifth Embodiment

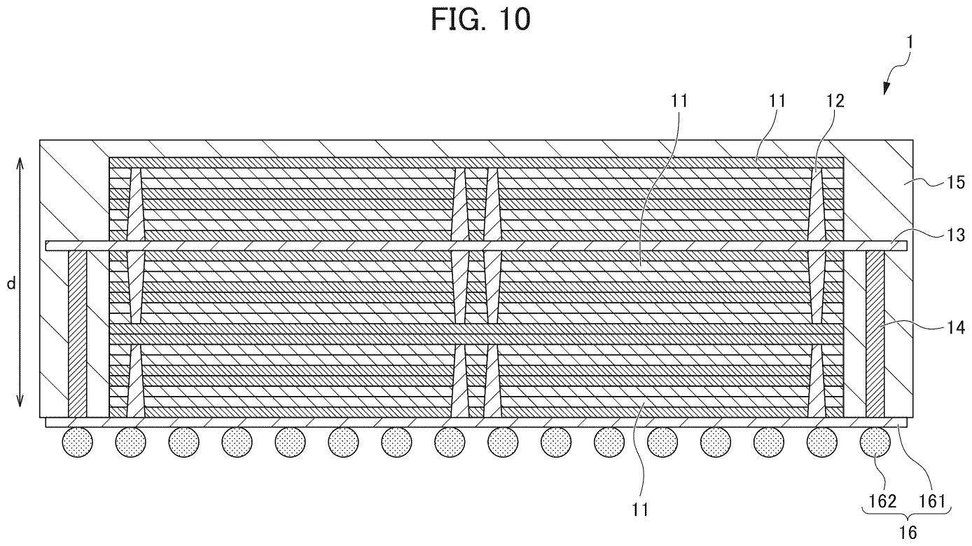

Next, a module 1 according to a fifth embodiment of the present invention and a manufacturing method thereof will be described with reference to FIG. 10. In the fifth embodiment, the same components as those described above are denoted by the same reference numerals, and the description thereof is simplified or omitted. The module 1 according to the fifth embodiment differs from that of the first embodiment in that according to the fifth embodiment, a further stacked memory 11 is disposed over the stacked memories 11. The manufacturing method of the module 1 according to the fifth embodiment differs from that of the first embodiment in that according to the fifth embodiment, after an internal redistribution layer forming step, a rearrangement step is performed in which the further stacked memory 11 is disposed on the internal redistribution layer 13 in the stacking direction d. The manufacturing method of the module 1 according to the fifth embodiment differs from that of the fifth embodiment in that, according to the fifth embodiment, molding is performed after the further stacked memory 11 has been disposed on the internal redistribution layer 13.

The above-described module 1 and manufacturing method thereof according to the fifth embodiment make it possible to produce a module 1 having a lager capacity.

### Sixth Embodiment

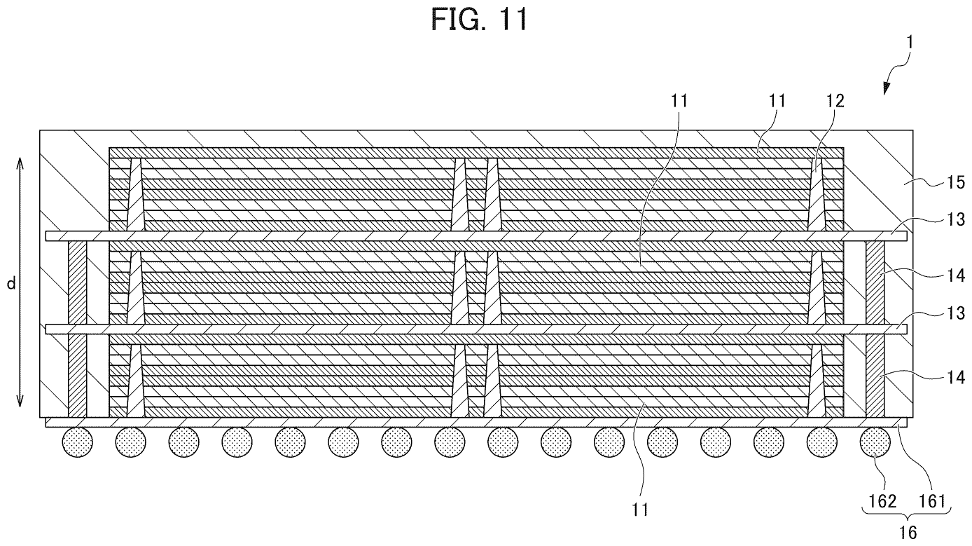

Next, a module 1 according to a sixth embodiment of the present invention and a manufacturing method thereof will be described with reference to FIG. 11. In the sixth embodiment, the same components as those described above are denoted by the same reference numerals, and the description thereof is simplified or omitted. The module 1 according to the sixth embodiment differs from those of the first and third embodiments in that according to the sixth embodiment, a plurality of internal redistribution layers 13 are interposed between the stacked memories 11. The sixth embodiment further differs from the first and third embodiments in that the sixth embodiment include a plurality of external through electrodes 14 in the stacking direction d. The manufacturing method of the module 1 according to the sixth embodiment differs from those of the first and third embodiments in that, according to the sixth embodiment, after an internal redistribution layer forming step, a rearrangement step is performed in which a stacked memory 11 is disposed on the internal redistribution layer in the stacking direction d. The manufacturing method of the module 1 according to the sixth embodiment differs from those of the first and third embodiments in that according to the sixth embodiment, molding is performed after the stacked memory 11 has been disposed on the internal redistribution layer. The manufacturing method of the module 1 according to the sixth embodiment differs from those of the first and third embodiments in that according to the sixth embodiment, the foregoing steps are repeatedly performed.

The above-described module 1 and manufacturing method thereof according to the sixth embodiment makes it easier to manufacture the modules 1 having a large capacity by repeating the steps.

### Seventh Embodiment

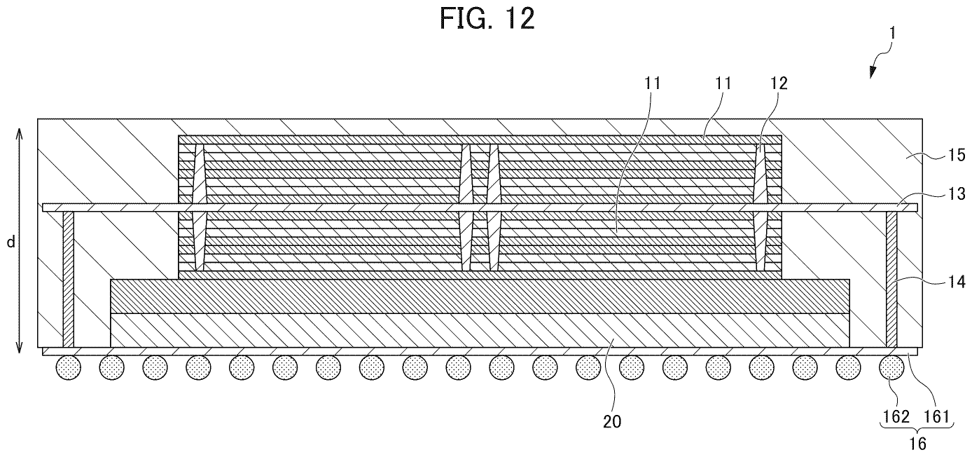

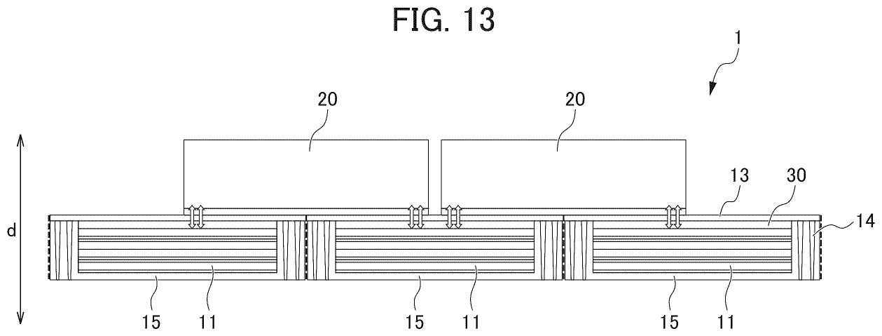

Next, a module 1 according to a seventh embodiment of the present invention and a manufacturing method thereof will be described with reference to FIG. 12. In the seventh embodiment, the same components as those described above are denoted by the same reference numerals, and the description thereof is simplified or omitted. The module 1 according to the seventh embodiment differs from that of the third embodiment in that according to the seventh embodiment, a further stacked memory 11 is disposed on the module 1 according to the third embodiment. The module 1 according to the seventh embodiment differs from that of the second embodiment in that, instead of the configuration of the module 1 of the second embodiment, the stacked memories 11 are disposed over a logic chip 20 and molded.

The above-described module 1 and manufacturing method thereof according to the seventh embodiment make it easy to manufacture the module 1 having a larger capacity. Furthermore, the seventh embodiment makes it possible to reduce the manufacturing cost of the module 1.

### Eighth Embodiment

Next, a module 1 according to an eighth embodiment of the present invention and a manufacturing method thereof will be described with reference to FIG. 13. In the eighth embodiment, the same components as those described above are denoted by the same reference numerals, and the description thereof is simplified or omitted. The module 1 according to the eighth embodiment differs from those of the first to seventh embodiments in that according to the eighth embodiment, a plurality of logic chips 20 are disposed on stacked memories 11 juxtaposed to each other in a direction intersecting with a stacking direction d such that each logic chip 20 straddles the stacked memories 11. The module 1 of the eighth embodiment differs from those of the first to seventh embodiments in that according to the eighth embodiment, each stacked memory 11 includes a plurality of memory chips 110 and a control chip 30 that is exposed on one surface in the stacking direction d and controls the operation of the memory chips 110. Furthermore, the manufacturing method of the module 1 according to the eighth embodiment differs from those of the first to seventh embodiments in that in a rearrangement step according to the eighth embodiment, the logic chips 20 are disposed over the control chips 30 that are exposed on one surface of a stacked wafer in the stacking direction d and that control the operation of the stacked memories 11. Furthermore, the method for manufacturing the module 1 according to the eighth embodiment differs from those of the first to seventh embodiments in that according to eighth embodiment, the logic chips 20 are arranged in the rearrangement step before a semifinished product is separated into the molded stacked memories 11, and thereafter, the molded stacked memories 11 each including a predetermined number of the logic chips 20 are produced by way of the separation.

Each control chip 30 is disposed adjacent to the internal redistribution layer 13 in the stacking direction d of the stacked memories 11. Each control chip 30 includes, for example, a memory controller, a memory interface, an arbiter circuit, a router, a switch, etc. In the eighth embodiment, the bidirectional arrows crossing the connection surface between the control chip 30 and the logic chip 20 indicate communication paths between the control chip 30 and the logic chip 20, and a non-contact communication means such as magnetic field communication or capacitive coupling communication may be used as a communication method. Alternatively, hybrid connection or connection using micro bumps may be used. In this case, the internal redistribution layer 13 do not have to be provided. On a lower surface of the packaging part 15 that covers a surface of the stacked memory 11 (chip) opposite in the stacking direction d to a surface on which the control chip 30 is disposed, external wiring 16 (not shown) including an external redistribution layer 161 and solder balls 162 may be provided.

The above-described module 1 and manufacturing method thereof according to the eighth embodiment make it possible to stack the logic chips 20 on the stacked memories 11 after rearrangement of selecting non-defective stacked memories 11, thereby enabling improvement of the yield. Furthermore, since the separated pieces can include an arbitrary number of logic chips 20, MCMs can be manufactured in a scalable manner.

### Ninth Embodiment

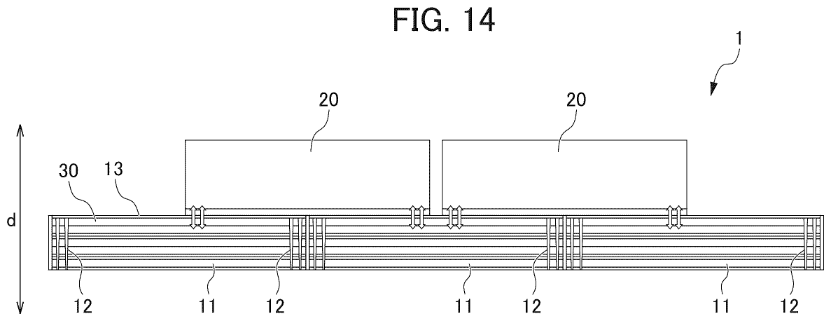

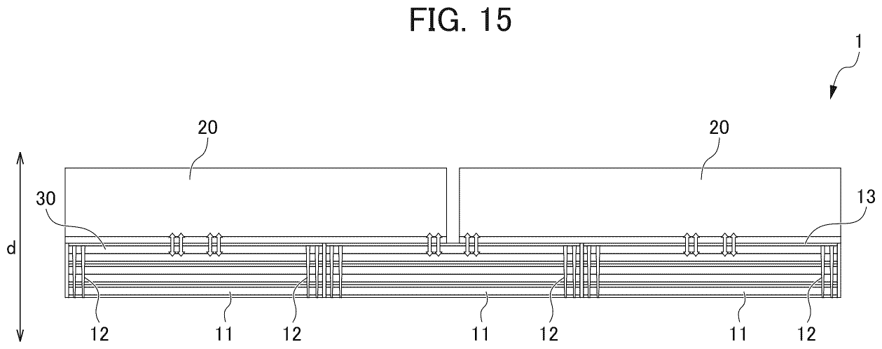

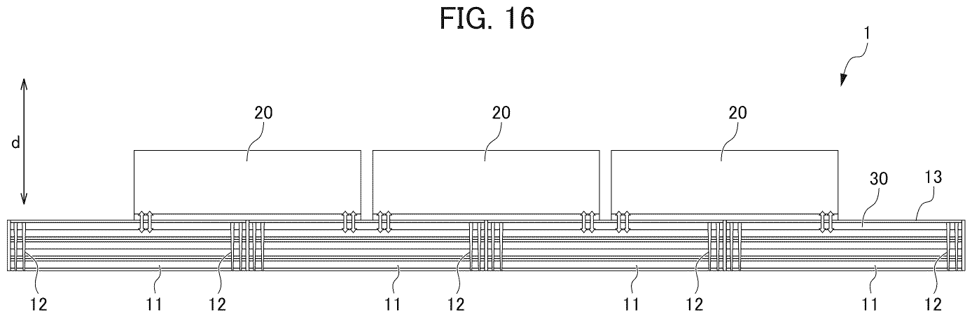

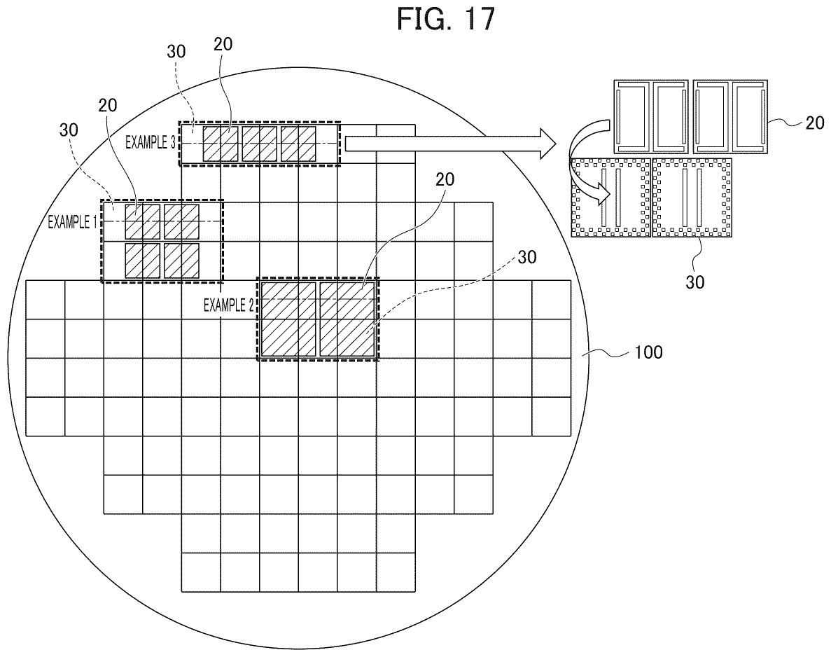

Next, a module 1 and a manufacturing method thereof according to a ninth embodiment of the present invention will be described with reference to FIGS. 14 to 17. In the ninth embodiment, the same components as those described above are denoted by the same reference numerals, and the description thereof is simplified or omitted. As illustrated in FIGS. 14 to 17, the modules 1 of the ninth embodiment differ from those of the first to eighth embodiments in that according to the ninth embodiment, the logic chips 20 are disposed on a stacked wafer such that each logic chip 20 straddles stacked memories 11, and thereafter, a resultant semifinished product is separated. The manufacturing method of the modules 1 of the ninth embodiment differs from those of the first to eighth embodiments in that the method of the ninth aspect does not include a dicing step or a molding step. In the present embodiment, three types of modules 1 will be described as examples. For example, as illustrated in FIGS. 14 and 17, the first module 1 has a configuration in which two processors are disposed on six stacked memories 11 (cross-section example 1). For example, as illustrated in FIGS. 15 and 17, the second module 1 has a configuration in which two logic chips 20 having a larger size are disposed on six stacked memories 11 (cross-section example 2). As illustrated in FIGS. 16 and 17, the third module 1 has a configuration in which three logic chips 20 are disposed on four stacked memories 11 (cross-section example 3). Each of the modules 1 of the ninth embodiment includes control chips and an internal redistribution layer 13 on one exposed surface of a stacked wafer. Instead of the stacked wafer, as in the eighth embodiment (FIG. 13), a component may be used which is obtained by molding stacked chips 11 as individual pieces and external through electrodes 14 rearranged on a carrier substrate 200, and by forming an internal redistribution layer 13. In the ninth embodiment, the bidirectional arrows crossing the connection surface between the control chip 30 and the logic chip 20 indicate communication paths between the control chip 30 and the logic chip 20, and a non-contact communication means such as magnetic field communication or capacitive coupling communication may be used as a communication method. Alternatively, hybrid connection or connection using micro bumps may be used. In this case, the internal redistribution layer 13 do not have to be provided. On a lower surface of the stacked memory chip 11 opposite in the stacking direction d to a surface on which the control chip 30 is disposed, external wiring 16 (not shown) including an external redistribution layer 161 and solder balls 162 may be provided.

The above-described module 1 and manufacturing method thereof according to the ninth embodiment exert the following effects.
(5) The module 1 includes a plurality of stacked memories 11 each including memory chips 110 stacked by bump-less connection, and the logic chip 20 disposed on the stacked memories 11 juxtaposed to each other in a direction intersecting with the stacking direction d such that the logic chip 20 straddles the stacked memories 11. The method for manufacturing the module 1 including a predetermined number of stacked memories 11 includes: a stacked wafer forming step of forming a stacked wafer by stacking a plurality of memory wafers 100 in a bump-less manner; a rearrangement step of arranging the logic chips 20 such that each logic chip 20 straddles a plurality of stacked memories 11 included in the stacked wafer; and a separation step of separating the stacked wafer having the logic chips 20 arranged thereon into a memory modules 1 each including the predetermined number of the stacked memories 11. Thus, the logic chips 20 are arranged on the stacked wafer including wafers stacked in a bump-less manner, or on a panel formed by rearranging individual pieces obtained by dicing the stacked wafer, and thereafter the resultant semifinished product is diced into the modules 1 as individual pieces. This feature makes it easier to align the chips as the individual pieces with each other, in comparison with a case where chips as individual pieces are arranged one-by-one and connected to each other. In addition, since the logic chips 20 are arranged on the stacked wafer including wafers stacked in a bump-less manner, or on a panel formed by rearranging individual pieces obtained by dicing the stacked wafer, the degree of freedom of arrangement of the logic chips and density of the logic chips can be increased. Furthermore, each logic chip can be arranged so as to straddle a plurality of memories, and the number of logic chips and the number of memories can be determined in a scalable manner.

In the foregoing, some preferred embodiments of the module of the present invention and the manufacturing method thereof have been described. It should be noted that the present invention is not limited to the above-described embodiments and can be appropriately modified.

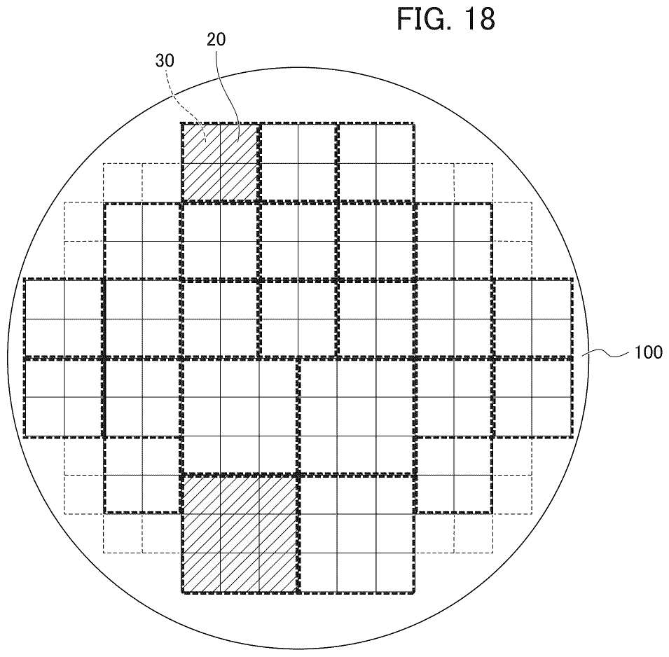

For example, in the ninth embodiment, the size of the logic chip 20 can be appropriately changed as illustrated in in FIG. 18. One logic chip 20 may be arranged so as to straddle a plurality of stacked memories 11. Furthermore, in the module 1, instead of disposing a plurality of logic chips 20, one logic chip 20 may be disposed so as to straddle a plurality of stacked memories 11.

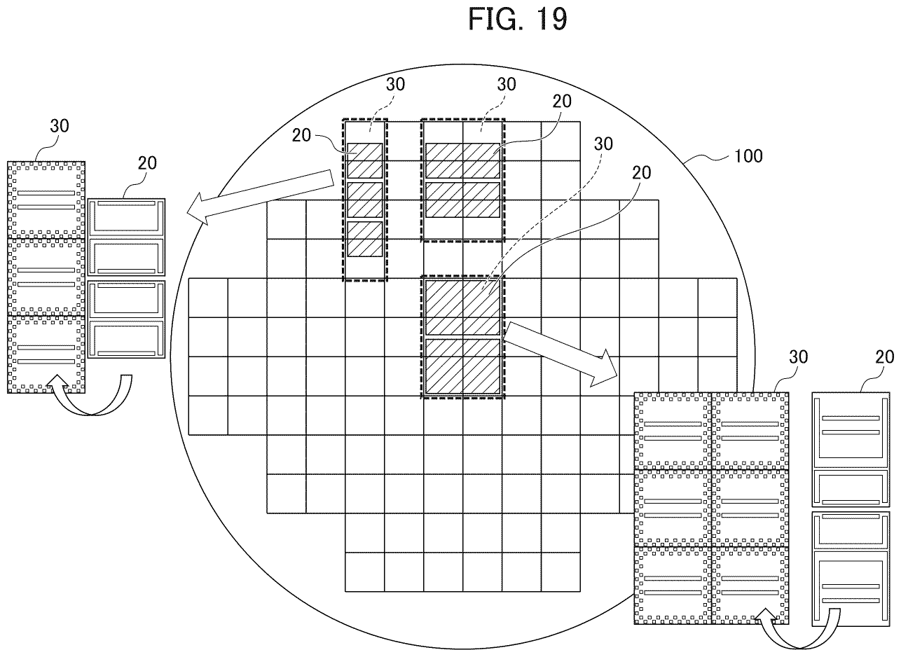

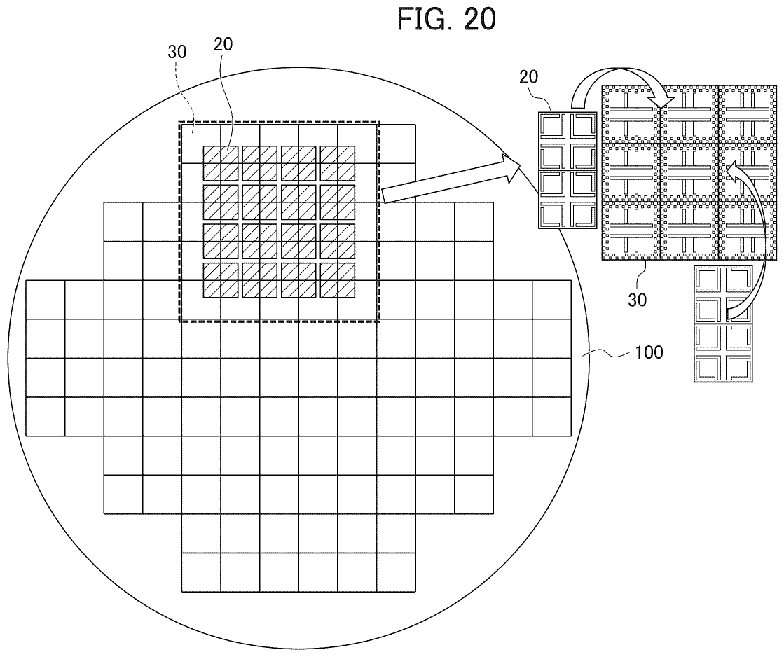

In the ninth embodiment, as illustrated in FIGS. 19 and 20, separation positions at which a stacked wafer is separated may be freely changed according to the number of memories necessary for the module 1 and the shape of the logic chip 20. A connection terminal of the logic chip 20 may be designed in accordance with the position of a connection terminal of the stacked memory 11 and the shape of the logic chip 20. In FIGS. 17 to 20, each rectangular area shown on the connection surface between the control chip 30 and the logic chip 20 indicates an electrical connection terminal between the control chip 30 and the logic chip 20.

In the eighth embodiment and the ninth embodiment, after the logic chips 20 are disposed, the entirety of the resultant semifinished product may be molded and then separated into the modules 1.

According to the above-described embodiment and the second embodiment, in a case where the stacked memories 11 or the logic chip 20 are/is juxtaposed in a direction intersecting with the stacking direction d, it is not necessary to stack the stacked memories 11 or the logic chip 20. In this case, the external through electrode 14 may be omitted from the module 1.

In addition, among the internal through electrodes 12 of the stacked memory 11, one or more that transmit a signal may use a non-contact communication means such as magnetic field communication or capacitive coupling communication. The internal through electrodes 12 may have a structure in which electrodes penetrate the respective memory chips and the electrodes are hybrid-connected to each other at connection surfaces. These are examples of electrical connection means for bump-less connection.

### EXPLANATION OF REFERENCE NUMERALS

1: Module
11: Stacked memory
12: Internal through electrode
13: Internal redistribution layer
14: External through electrode
15: Packaging part
16: External wiring
20: Logic chip
30: Control chip
100: Memory wafer
200: Carrier substrate
d: Stacking direction

1. A module including a plurality of stacked memories, the module comprising:
the plurality of stacked memories each including memory chips stacked by bump-less connection; and
a logic chip stacked on the stacked memories that are juxtaposed to each other in a direction intersecting with a stacking direction of the stacked memories in such a manner that the logic chip straddles the stacked memories.

2. The module according to claim 1, wherein each stacked memory comprises the memory chips, and a control chip that is exposed on one surface in a stacking direction and controls operation of the memory chips.
